(19) United States
(12) Patent Application Publication
(10) Pub. No.: US 2013/0042915 A1
(43) Pub. Date: Feb. 21, 2013

(54) PHOTOVOLTAIC SOLAR CONCENTRATION SYSTEM

(71) Applicants: Sebastian Caparros Jimenez, Sevilla (ES); Thomas Lewis Rowley Davenport, Tucson, AZ (US)

(72) Inventors: Sebastian Caparros Jimenez, Sevilla (ES); Thomas Lewis Rowley Davenport, Tucson, AZ (US)

(73) Assignee: Abengoa Solar New Technologies, S.A., Sevilla (ES)

(21) Appl. No.: 13/579,647

(22) PCT Filed: Feb. 2, 2011
(86) PCT No.: PCT/ES11/70065

§ 371 Date: Oct. 29, 2012

(30) Foreign Application Priority Data
Feb. 19, 2010 (ES) P201030241

(51) Int. Cl. H01L 31/0232

(52) U.S. Cl. 136/259

(57) ABSTRACT

A concentrated photovoltaic solar system has a Fresnel lens concentrator (1) with a constant facet thickness in a first zone, a the central area of the lens (1), then has a constant facet height in a second zone at the peripheral area of the lens (1), in order to maximize the optical efficiency of the lens (1) and maintain the typical system aberrations under control. The concentrated photovoltaic solar system also includes a secondary optical element 2 with a circular intake face (3) and convex curvature, a section to accommodate a rim (4), and a pyramid section (6), the transverse section changing from a circle into a square in the lower end (7) where the photovoltaic receiver is housed. This system improves optical and thermodynamic efficiency of existing systems, facilitates the production and installation in the photovoltaic module, and reduces manufacturing-related costs.

### FIELD OF THE INVENTION

The present invention refers to the technical field of concentrated photovoltaic solar systems for the harnessing of solar energy for the production of electric energy, particularly to high-concentration concentrated photovoltaic solar systems, and more particularly to systems formed mainly by a Fresnel lens concentrator, a secondary optical element and a photovoltaic receiver.

### BACKGROUND OF THE INVENTION

Numerous concentrated photovoltaic (CPV) solar systems have been proposed and developed along the 20th century until our days. In spite of this long history, these systems are not competitive nowadays in terms of cost and efficiency with respect to traditional forms of energy production.

Documents WO2006114457, US2009106648 and WO 2009058603 show the typical working scheme of a concentrated photovoltaic solar system. Said system consists of a Fresnel lens light concentrator and a secondary optical element which provides the system with greater concentration. Several systems using Fresnel lenses have been proposed with and without secondary optical elements.

There exist other concentrated photovoltaic solar systems based on the Cassegrain technology. Said systems consist of a pair of mirrors and a tertiary homogenizing optical element. Also, there are other concentrated optical elements based on parabolic mirrors. Said systems can be formed by mirrors or they can be a completely solid system based on Total Internal Reflection (TIR), as shown in documents WO2009058603 and WO2009086293.

Recently, there have been reported light-guiding concentrated systems , as shown in document WO2008131566. Said systems are characterized by their greater compactness vis-à-vis traditional systems.

An ideal concentrated photovoltaic solar system should include the following characteristics to be competitive: minimizing losses in optical concentrated systems, that is, attaining greater optical efficiency; being an effective solution in cost and reliable in the long term; being compact and attaining maximum thermodynamic efficiency, that is, attaining the maximum degree of concentration possible, maintaining minimum manufacturing clearances.

Also, an ideal concentrated photovoltaic solar system should maximize the use of the etendue. The concept of etendue was described by Dr. Winston and Co. in Non Imaging Optics and is of great importance in a concentrated photovoltaic solar system. Maximizing the etendue means maximizing the acceptance angle of a system for a particular concentration degree, or maximizing the concentration for a particular acceptance angle. A module of maximum use of etendue has potential to effectively concentrate solar radiation, minimizing the cost of the semiconductor element and consequently the module, and provide the system with the necessary tolerance to be mounted in real solar tracking systems, and allow manufacturing clearance of the module without that affecting the performance thereof.

The maximum degree of concentration that can be reached for an acceptance angle is defined by the following equation:

$$C max = \frac{( {n}^{2} \cdot {seno ( {θ}_{1} )}^{2} )}{{( seno ( {θ}_{2} ) )}^{2}}$$

Where n is the refractive index of the medium in which the photovoltaic receiver is submerged, θ1 the intake angle in the photovoltaic cell and θ2 the acceptance angle in the system.

The concentrated photovoltaic solar systems through Fresnel lenses are the most widely used, since it is a known, standard and cost-effective technology. However, they are not excessively compact systems and they do not maximize the use of the etendue. Yet there have been published certain documents with the object of maximizing the use of the etendue using lens systems with very high focal lengths and secondary elements with certain curvature at the intake.

The reflexive systems are being progressively introduced, in general they are more compact than refractive systems, and with the appropriate design they maximize the use of etendue in comparison with lenses. However, they have smaller optical efficiencies and a greater number of elements.

The light-guiding systems are, by far, the most compact ones. However, they still have to show their optical efficiency, cost and reliability in the long term.

It was therefore desirable a system which attained a high photovoltaic solar concentration avoiding the existing inconveniencies in the previous systems of the state of the art.

### DESCRIPTION OF THE INVENTION

The present invention solves the existing problems in the state of the art by means of a concentrated photovoltaic solar system formed by a Fresnel lens concentrator, a secondary optical element and a photovoltaic receiver.

Fresnel lenses can usually be defined with two forms: with a constant facet thickness (equi-pitch), or with a constant facet height (equi-depth). Each one has its advantages and disadvantages.

Every design of a Fresnel lens tends to compensate two factors, one with the other: First, making the lens as efficient as possible, which is attained by maximizing the ratio between the facet thickness and its rounding in the peak, due to the film or moulding production process.

Second, controlling the lens aberrations, which is attained basically by controlling the focal length into appropriate values and making the facet thickness as small as possible.

Compensating both effects is antagonistic. If it is intended to maximize the thickness with respect to the peak we have to use a constant height design. A constant height design has the central facets of the lens with a thickness that is too high, causing the off-axis behaviour of the lens due to aberrations not to be the desired one. This would reduce the acceptance angle of the system.

By contrast, a constant thickness design is usually made with a constant thickness in all facets which is less than 1 mm, which causes the off-axis behaviour to be relatively better than in the previous case; however, the rounded peak occupies greater relative space in the total lens, making it less efficient.

The solution proposed in the present invention is a hybrid lens which has the advantages of both types of design. The central part of the lens will have a constant thickness of 1 mm or less. As more facets are introduced, a maximum height point of said facet will be achieved (which depends on what each provider specifies according to their process). Once we arrive at this point, the design becomes a constant height design. Therefore, they are hybrid lenses, with constant thickness in the middle and constant height in the peripheral area.

This type of designs have the advantage of improving a couple of points the efficiency of the lens, presenting an acceptable behaviour with respect to off-axis aberrations, thus increasing the acceptance angle of the system.

The secondary optical elements have to be placed in the appropriate position in order to maximize the use of etendue. Dr. Winston described designs which enabled to attain reaching optical limits. Said limits were reached with F#=3, F# being =f/D, being:
f=focal length of the lens,
D=diagonal of the light intake face of the lens.

The optical elements of the lenses of the concentrated systems object of the present invention reach the limits in a quite lower F# range. A low F# implies more compact systems and reduced sized pieces, which leads to more cost-effective solutions.

The following table shows an increase in the system use of etendue as the F# increases.

| | | | Acceptance | | Square | |
|---|---|---|---|---|---|---|
| Case | F# | Real Cx | angle (°) | Cmax | Cmax | Etendue % |
| 1 | 0.9 | 700 | 1.45 | 2882.5 | 1441.3 | 48.6% |
| 2 | 1.1 | 700 | 1.85 | 1771.0 | 885.5 | 79.1% |
| 3 | 1.2 | 700 | 1.91 | 1661.5 | 830.8 | 84.3% |
| 4 | 1.3 | 700 | 1.93 | 1627.3 | 813.7 | 86.0% |
| 5 | 1.4 | 700 | 1.94 | 1610.6 | 805.3 | 86.9% |
| 6 | 1.5 | 700 | 1.98 | 1546.2 | 773.1 | 90.5% |

An important increase in the system efficiency is observed when F# is changed from 0.9 (practical minimum in real systems) to 1.2. From this point of view the improvement is greatly relativized, the curve presenting asymptotic behaviour. Therefore, it is not convenient to use lenses with F# greater than 1.5 in these systems, since it would increase the cost of the system without providing any significant improvement. A compromise situation where F#=1.2 has been estimated.

The secondary optical elements to be coupled with lenses comprised between the specified F# are characterized by a convex curve intake, a section to accommodate the rim and a truncated pyramid, the transverse section changing from circular into square, where the photovoltaic receiver will be housed.

The intake face has a circular intake section and is convex so that it adds optical capacity to the secondary optical element, allowing more compact structures and improving the efficiency. Said face is circular, due to the fact that said configuration enables a better capture of rays than the equivalent square surface, thus increasing the angular tolerance of the complete lens-secondary system.

Next, there is an inactive or active area where the rim is housed. Said rim entails an advantage in moulding manufacturing processes and allows the mechanic coupling of the secondary element inside the module. Likewise, it facilitates the post-processing of the pieces once they have been moulded. The rim can be integrated or not in the mould.

Finally, there is a truncated pyramid section which has an initial circular section coupled to the rim, and an output square section, necessary to couple the chip. This type of secondary elements enable moulding processes with a minimum requirement for polish, minimizing operation times and piece costs. Also, the very high thermodynamic efficiency which can be reached with these designs is verified.

These secondary elements have the great advantage with respect to more conventional designs that they reach equal or higher degrees of concentration while providing a good acceptance angle which does not compromise the design of the tracker and the mounting process of the module itself, making this technology a very attractive one.

### DESCRIPTION OF THE DRAWINGS

The following is a description of an embodiment of the invention presented as a non-limiting example thereof which will facilitate the understanding of the invention referring to a series of drawings.

FIG. 1 shows a typical operation scheme of a concentrated photovoltaic solar system known in the state of the art.

FIG. 2 shows the operation of another concentrated photovoltaic solar system based on the Cassegrain technology, also known in the state of the art.

FIG. 3 shows concentration optical elements based on parabolic mirrors, existing in the state of the art.

FIG. 4 shows a light-guiding concentrated system, already existing in the state of the art.

FIG. 5 shows the relation existing between thickness and roundness of a Fresnel lens concentrator.

FIG. 6 shows the relation between F# and etendue of the system object of the present invention.

FIG. 7 shows several views of the secondary optical element object of the present invention.

FIG. 8 shows the parameters of a preferred embodiment of the lens of the system object of the present invention.

FIG. 9 shows a preferred embodiment of the secondary optical element of the system object of the present invention.

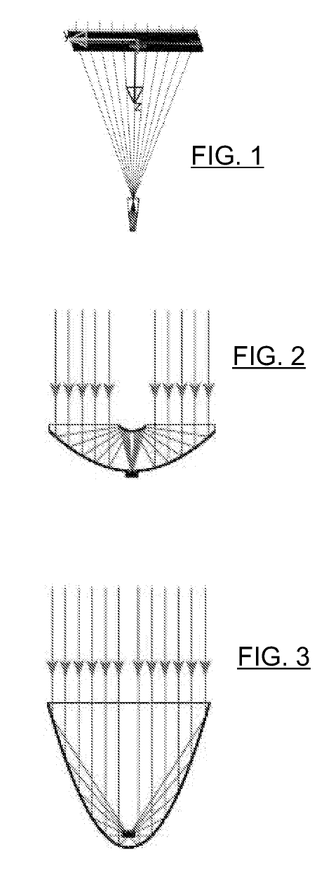

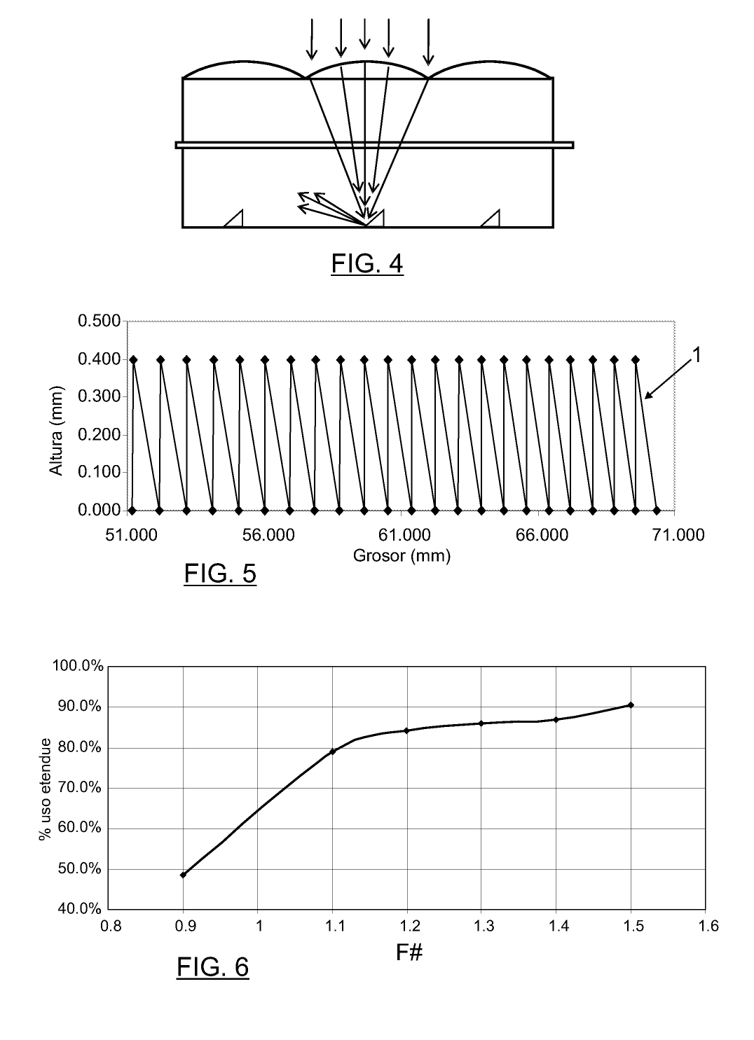

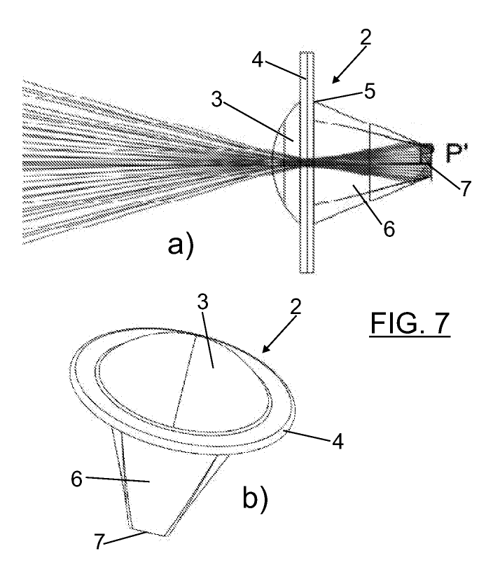

In these figures reference is made to a set of elements which are the following:
1. Fresnel lens concentrator
2. secondary optical element
3. intake face of the secondary optical element
4. rim of the secondary optical element
5. circular transverse section
6. pyramid section of the secondary optical element
7. lower end of the pyramid section of the secondary optical element

### DESCRIPTION OF PREFERRED EMBODIMENTS OF THE INVENTION

Next, there is a detailed description of a preferred embodiment of the design parameters describing the Fresnel lens concentrator 1 and the secondary optical element 2.

The system described is defined by a geometrical concentration of 1000× concentrating the radiation in a 5.5×5.5 mm² photovoltaic cell. This defines a 174×174 mm² Fresnel lens concentrator 1. The F# of the lens 1 has been fixed in 1.2. Said value is considered a compromise between system compactness and use of etendue.

The design of the lens 1 is fixed in the following manner:

The central part of the lens has a constant thickness design of 1 mm. Said thickness enables to have a lens with good efficiency and good off axis behaviour, thus improving the system acceptance angle.

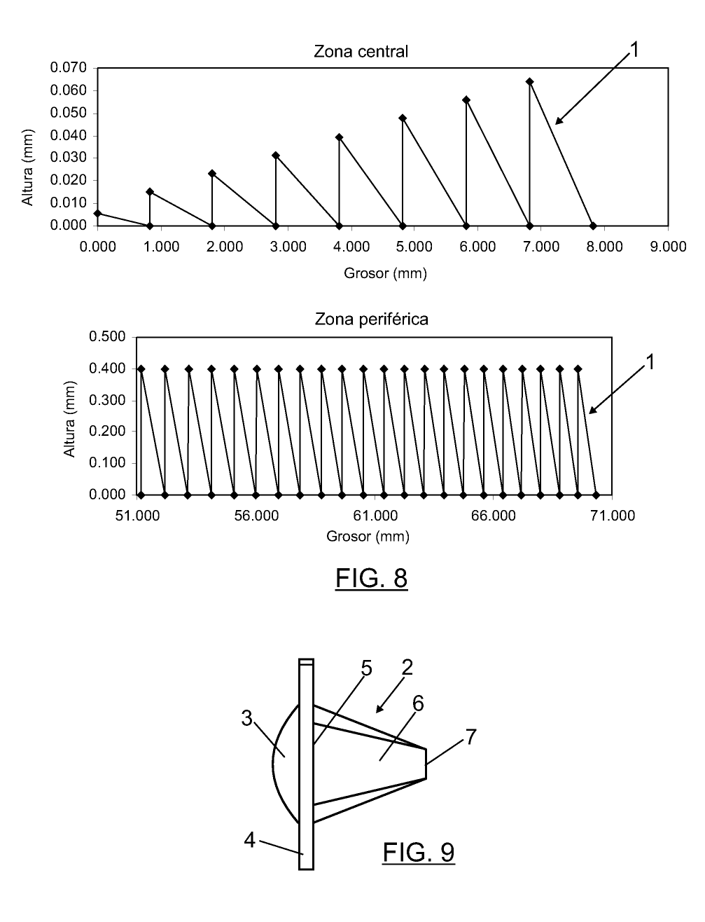

Once a maximum of 0.4 mm height is reached for the lens facet height, said maximum is maintained until reaching the outer edge of the facet. FIG. 8 shows the profile of said hybrid lens.

The secondary optical element 2 has been optimized for an acceptance angle of 1.4°. FIG. 9 shows the design of the secondary optical element 2, which together with the Fresnel lens concentrator 1 is capable of fixing the performance of 1000× and the acceptance angle of 1.4°.

Another preferred embodiment of the concentrated photovoltaic solar system object of the present invention is defined by a geometrical concentration of 700× with the F# of the lens 1 fixed in 1.2 and a secondary optical element 2 with an acceptance angle of 1.91°.

FIG. 6 shows the relation between F# and the etendue of the system object of the present invention.

According to a preferred embodiment of the invention which can be observed in the drawings, the secondary optical element 2 has a curve convex intake face 3, and a truncated pyramid section 6 in its lower part. Also, the system comprises a rim 4 arranged around the intake face 3 of the secondary optical element 2, said rim having a square or circular shape. This rim 4 can be optically active, or inactive, and it can be made in a part integral to the secondary optical element 2, or in a manner independent from it.

Preferably, the secondary optical element 2 has next to the intake face 3 a circular transverse section 5, which is progressively transformed into a square transverse section until reaching the lower end 7 of the truncated pyramid section 6, said lower end 7 being where the photovoltaic receiver is fixed.

Once the invention has been clearly described, it is highlighted that the particular embodiments described above can be modified in detail as long as they do not alter the fundamental principle and essence of the invention.

1. Concentrated photovoltaic solar system comprising
a Fresnel lens concentrator,
a secondary optical element, and
a photovoltaic receiver,
wherein the Fresnel lens concentrator is a hybrid lens comprising:
at least one first zone with a constant facet thickness, and
at least one second zone with a constant facet height.

2. The concentrated photovoltaic solar system according to claim 1, wherein the first zone with a constant facet thickness is a central area of the Fresnel lens concentrator.

3. The concentrated photovoltaic solar system according to claim 1, wherein the first zone of the Fresnel lens concentrator with the constant facet thickness has a thickness equal to or smaller than 1 mm.

4. The concentrated photovoltaic solar system according to claim 1, wherein the zone with constant facet height is a peripheral area of the Fresnel lens concentrator.

5. The concentrated photovoltaic solar system according to claim 2, wherein the Fresnel lens concentrator in the central area with constant thickness increases the facet height up to a maximum height point, as the number of facets of said Fresnel lens concentrator increases.

6. A concentrated photovoltaic solar system comprising:
a Fresnel lens concentrator,
a secondary optical element, and
a photovoltaic receiver
wherein
the secondary optical element in turn comprises a curve convex intake face, and
said secondary optical element has a truncated pyramid section.

7. The concentrated photovoltaic solar system according to claim 6, wherein the secondary optical element comprises a rim arranged around the intake face.

8. The concentrated photovoltaic solar system according to claim 1, wherein the rim has a geometrical shape selected between square and circular.

9. The concentrated photovoltaic solar system according to claim 7, wherein the rim of the secondary optical element is optically inactive.

10. The concentrated photovoltaic solar system according to claim 7, wherein the rim of the secondary optical element is optically active.

11. The concentrated photovoltaic solar system according to claim 7, wherein the rim is integral to the secondary optical element.

12. The concentrated photovoltaic solar system according to claim 7, wherein the rim is independent from the secondary optical element.

13. The concentrated photovoltaic solar system according to claim 6, wherein
the secondary optical element, next to the intake face comprises a circular transverse section, and
said circular transverse section progressively becomes a square transverse section until reaching a lower end of the truncated pyramid section of the secondary optical element.

14. The concentrated photovoltaic solar system according to claim 1, wherein the percentage of etendue in said concentrated photovoltaic solar system ranges between 45% and 95%.

15. The concentrated photovoltaic solar system according to claim 1, wherein
the Fresnel lens concentrator has
a focal length of said lens to the secondary optical element f, and
a diagonal of the light intake face in the lens D,
the relation F#=f/D ranging between 0.9 and 1.5, and
the secondary optical element has an acceptance angle ranging between 1.20° and 1.99°.

16. The concentrated photovoltaic solar system according to claim 1, further comprising:
a geometrical concentration of 1000×,
a Fresnel lens concentrator with a relation F#=1.2, and
a secondary optical element with an acceptance angle of 1.4°.

17. The concentrated photovoltaic solar system according to the claim 1, wherein:
the constant thickness of the facet in the central area of the Fresnel lens concentrator (1) is smaller than or equal to 1 mm, and
in said central area the height of the facet increases in a progressive manner until reaching a maximum height of 0.4 mm, said maximum height of 0.4 mm being kept constant until the facet of the outer edge of the Fresnel lens concentrator.

18. The concentrated photovoltaic solar system according to the claim 1, comprising:
a geometrical concentration of 700×,
a Fresnel lens concentrator with a relation F#=1.2, and
a secondary optical element with an acceptance angle of 1.91°.
